(19) United States
(12) Patent Application Publication
(10) Pub. No.: US 2011/0081760 A1
(43) Pub. Date: Apr. 7, 2011

(54) METHOD OF MANUFACTURING LATERAL DIFFUSION METAL OXIDE SEMICONDUCTOR DEVICE

(76) Inventor: Bo-Jui Huang, Hsinchu City (TW)

(21) Appl. No.: 12/571,451

(22) Filed: Oct. 1, 2009

(51) Int. Cl. H01L 21/336

(52) U.S. Cl. 438/286; 438/297; 257/E21.417

(57) ABSTRACT

A method of manufacturing a lateral diffusion metal oxide semiconductor device includes following steps. First, a substrate having a first conductive type is provided. The substrate has a well, and the well has a second conductive type. Then, a body region is formed in the well, and a channel defining region is formed in the body region. The body region has the second conductive type, and the channel defining region has the first conductive type, so that the body region disposed between the channel defining region and the well and uncovered with the channel defining region forms a channel of the lateral diffusion metal oxide semiconductor device. Then, a gate structure is formed on the channel.

### BACKGROUND OF THE INVENTION

1. Field of the Invention

The present invention relates to a method of manufacturing a lateral-diffusion metal-oxide-semiconductor (LDMOS) device, and more particularly, to a method of manufacturing an LDMOS with a stable channel length.

2. Description of the Prior Art

A metal-oxide-semiconductor (MOS) device is a common electrical device used in integrated circuits. The MOS device is a semiconductor component, usually formed by a gate, a source and a drain. A gate voltage provided to the gate can induce electric charge between the source and the drain so as to form a channel of the MOS device, and the source and the drain can be electrically connected. Therefore, the MOS device is often made to function as a digitalized solid switch applied on various integrated circuits of memory or logic devices.

The lateral-diffusion MOS (LDMOS) device of the prior art includes a P type body region and a gate structure. The channel of the LDMOS device is constituted by the P type body region overlapping the gate structure, so the channel length is determined by the length of the part of the P type body region overlapping the gate structure. However, in the method of manufacturing the LDMOS of the prior art, when a photomask for defining the P type doped region is used to perform a lithographic process, the photomask pattern of the P type doped region is aligned to the former photomask pattern for defining the active area, and when a photomask for forming the gate structure is used to perform a lithographic process, the photomask pattern of the gate structure is also aligned to the former photomask pattern for defining the active area, so that the position of the photomask pattern for defining the P type doped region is indirectly aligned to the position of the photomask pattern for forming the gate structure. For this reason, the position of the photomask for forming the gate structure corresponding to the position of the photomask for forming the P type doped region easily has inaccuracy, which results in the misalignment of the relative position of the P type doped region and the gate structure. Accordingly, the size of the channel length will be also changed. With the small of the integral circuits, the change of the channel length is more sensitive to the operation of devices. Therefore, to manufacture an LDMOS device with a stable channel length is an important subject.

### SUMMARY OF THE INVENTION

It is therefore a primary objective of the present invention to provide a method of manufacturing a lateral-diffusion metal-oxide-semiconductor (LDMOS) device so as to have a LDMOS device with a stable channel length.

According to an embodiment of the present invention, a method of manufacturing a LDMOS device is provided. First, a substrate having a first conductive type is provided, and the substrate has a well with a second conductive type. Then, a body region having the first conductive type is formed in the well, and a channel defining region having the second conductive type is formed in the body region, wherein the body region disposed between the channel defining region and the well and uncovered with the channel defining region forms a channel of the LDMOS. Next, a gate structure is formed on the channel.

The present invention forms the channel defining region, the body region and the first well before forming the gate structure, and respectively performs corresponding high temperature drive-in process to fix the sizes so as to stabilize the channel length. Then, the gate structure is formed. For this reason, even the gate structure of the present invention formed on the substrate has misalignment in position, and the channel length disposed under the gate structure will not be affected on the condition that the gate structure covers the channel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a method of manufacturing a lateral-diffusion metal-oxide-semiconductor (LDMOS) device according to a first embodiment of the present invention.

FIG. 2 through FIG. 9 are schematic diagrams illustrating the method of manufacturing the LDMOS device according to the first embodiment of the present invention.

FIG. 10 is a flow chart illustrating an example of forming the body region and the channel defining region in step S20 according to the first embodiment.

FIG. 11 is a flow chart illustrating another example of forming the body region and the channel defining region in step S20 according to the first embodiment.

FIG. 12 is a flow chart illustrating a method of manufacturing the LDMOS device according to a second embodiment of the present invention.

FIG. 13 is a schematic diagram illustrating the method of manufacturing the LDMOS device according to the second embodiment of the present invention.

FIG. 14 is a flow chart illustrating a method of manufacturing the LDMOS device according to a third embodiment of the present invention.

### DETAILED DESCRIPTION

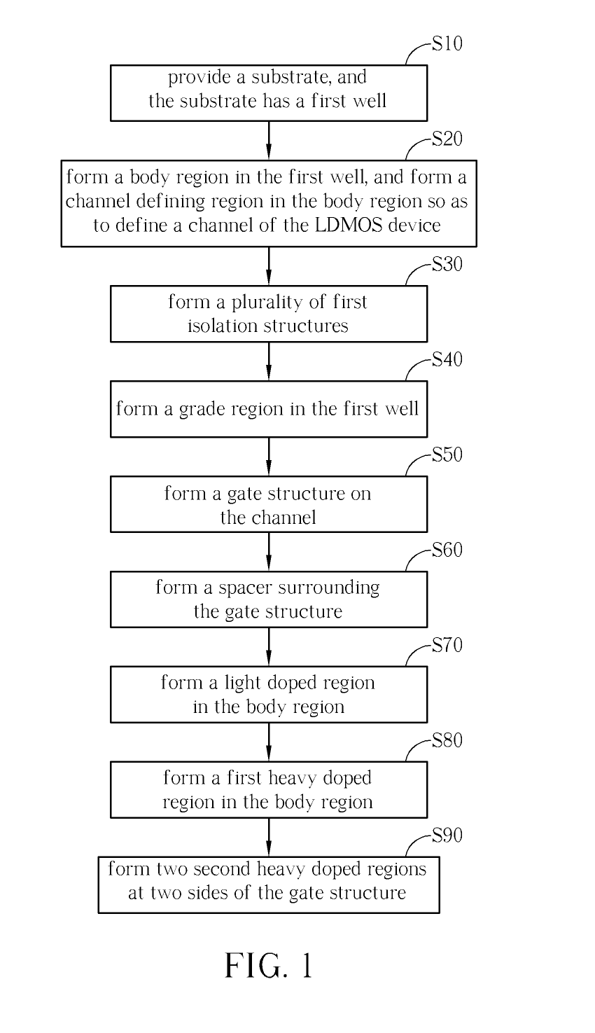

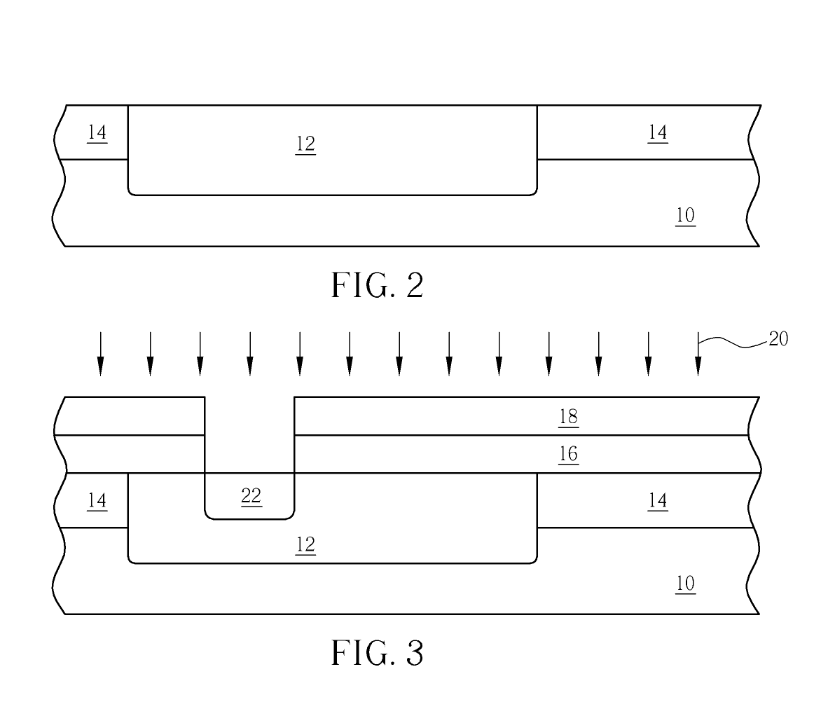

Please refer to FIG. 1 through FIG. 9. FIG. 1 is a flow chart illustrating a method of manufacturing a lateral-diffusion metal-oxide-semiconductor (LDMOS) device according to a first embodiment of the present invention. FIG. 2 through FIG. 9 are schematic diagrams illustrating the method of manufacturing the LDMOS device according to the first embodiment of the present invention. As shown in FIG. 1, the method of manufacturing the LDMOS device of this embodiment includes the following steps:

Step S10: provide a substrate having a first conductive type, and the substrate has a first well with a second conductive type;

Step S20: form a body region having the first conductive type in the first well, and form a channel defining region having the second conductive type in the body region, wherein the body region between the channel defining region and the first well and uncovered with the channel defining region forms a channel of the LDMOS device;

Step S30: form a plurality of first isolation structures at edges of the first well;

Step S40: form a grade region having the second conductive type in the first well;

Step S50: form a gate structure on the channel;

Step S60: form a spacer surrounding the gate structure;

Step S70: selectively form a light doped region having the second conductive type in the body region;

Step S80: form a first heavy doped region having the first conductive type in the body region; and

Step S90: form two second heavy doped regions having the second conductive type respectively in the body region between the first heavy doped region and the gate structure and in the first well of the other side of the gate structure opposite to the body region.

In order to clearly describe the method of manufacturing the LDMOS device of this embodiment, the following description is illustrated combined with FIG. 2 through FIG. 9. As shown in FIG. 2, in step S10, the substrate 10 is provided first, and the substrate 10 has a first conductive type. Next, a first well 12 having a second conductive type is formed in the substrate 10 by utilizing a first photomask (not shown in figure) to define an area of the required LDMOS device. This embodiment take the first conductive type being P type and the second conductive type being N type as an example, but the present invention is not limited to this. The first conductive type and the second conductive type of the present invention can be exchanged; this means that when the first conductive type is N type, the second conductive type is P type. Next, the method of this embodiment then utilizes a second photomask to form a P type second well 14 in the substrate. The present invention is not limited to have to form the second well 14, and is not limited to only form one first well 12. The position and number of the first well 12 and the second well 14 can be determined according to the sort and the number of the required devices. In addition, an ion implant process and a drive-in process used for forming the first well 12 and the second well 14 is known by the person skilled in the art, so the step of forming the first well 12 and the second well 14 will not describe in the following description.

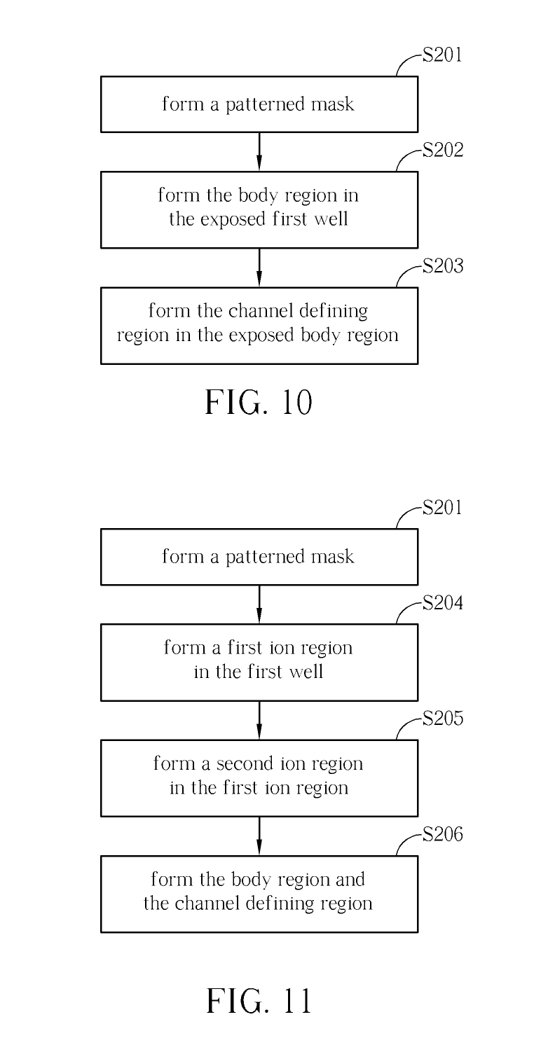

In addition, please refer to FIG. 10, and refer to FIG. 3 through FIG. 6 again. FIG. 10 is a flow chart illustrating an example of forming the body region and the channel defining region in step S20 according to the first embodiment. As shown in FIG. 10, the step S20 of this embodiment includes the following steps:

Step S201: form a patterned mask on the substrate to define positions of the body region and the channel defining region;

Step S202: perform a first ion implant process and a first drive-in process on the first well exposed by the patterned mask so as to form the body region in the first well; and

Step S203: perform a second ion implant process and a second drive-in process so as to form the channel defining region in the body region.

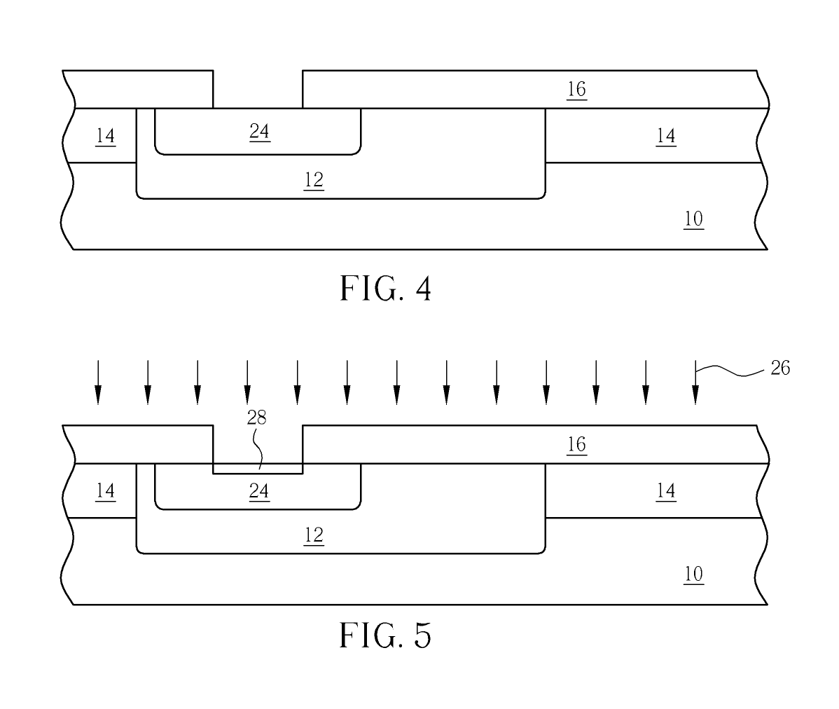

Next, as shown in FIG. 3, step S201 utilizes a second photomask to form a patterned photoresist layer 18 and a patterned mask 16 on the substrate 10 so as to expose a part of the first well 12. The patterned mask 16 is a hard mask, such as silicon nitride (Si₃N₄) being able to tolerate high temperature process, and is used to define the positions of the body region and the channel defining region (not shown in FIG. 3). In addition, the step of forming the patterned mask 16 and the patterned photoresist layer 18 is known by the person skilled in the art, so the step of forming the patterned mask 16 and the patterned photoresist layer 18 will not be described. Then, in step S202, the first P type ion implant process 20 is performed on a part of the first well 12 exposed by the patterned mask 16 and the patterned photoresist layer 18 so as to form a first ion implant region 22 in the first well 12. As shown in FIG. 4, after removing the patterned photoresist layer 18, the first drive-in process is then performed to diffuse doped ions in the first ion implant region (not shown in FIG. 4) so as to form the P type body region 24 in the first well 12. In addition, the step of removing the patterned photoresist layer 18 of the present invention is not limited to be performed between the first P type ion implant process 20 and the first drive-in process, and the patterned photoresist layer 18 can be removed before performing the first P type ion implant process 20.

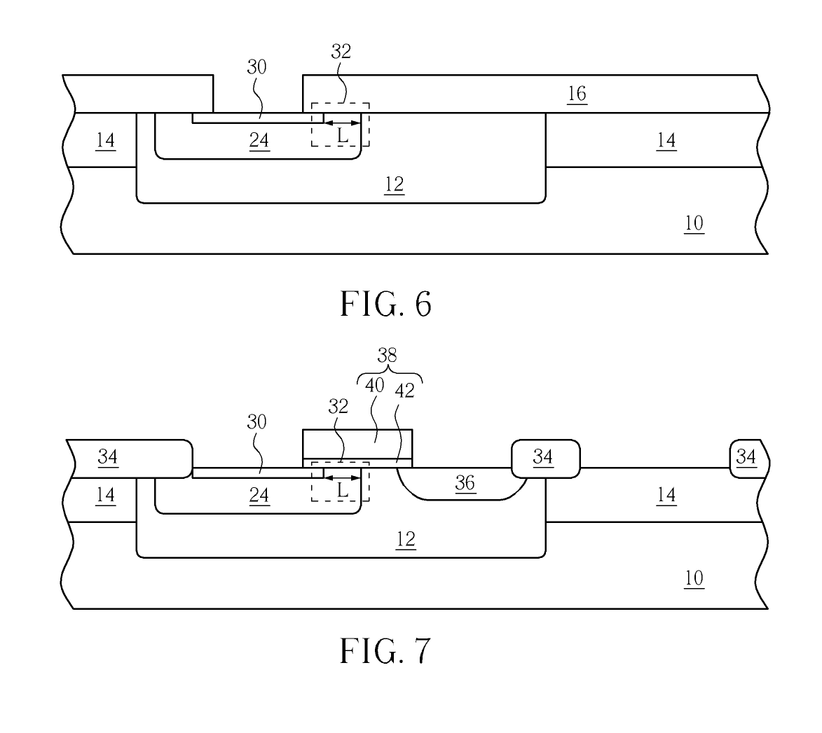

Then, as shown in FIG. 5, step S203 utilizes the same patterned mask 16 to be a mask for performing the second N type ion implant process on the body region 24 exposed by the patterned mask 16. Accordingly, the second ion implant region 28 is formed in the body region 24. Next, as shown in FIG. 6, a second drive-in process is performed to diffuse doped ions in the second ion implant region 28 so to form the channel defining region 30 having N type. The patterned mask 16 is then removed. It should be mentioned that the channel defining region 30, the body region 24 and the first well 12 constitute an NPN structure, so that the body region 24 between the channel defining region 30 and the first well 12 and uncovered with the channel defining region 30 can be as the channel 32 of the LDMOS device. Furthermore, the size of the channel defining region 30, the body region 24 and the first region 12 is substantially fixed after the second drive-in process; this means that the channel length L is substantially fixed. Therefore, even the gate structure formed in the following step has misalignment, and the channel length L will not be affected by the misalignment and can be a stable value on the condition that the gate structure covers the channel 32. In addition, the present invention further can selectively perform an annealing process after the second drive-in process so as to stabilize the doped ions in the channel defining region 30, body region 24 and the first well 12 and to avoid the change of the channel length L affected by the following high temperature process. The first P type ion implant process 20 and the second N type ion implant process 26 of the present invention are not limited to use the same patterned mask 16. The present invention also can remove the patterned mask 16 after forming the body region 24, and then, another photomask can be used to form another patterned mask on the substrate 10 according to the required position of the channel defining region 30. The second N type ion implant process 26 can be then performed.

However, step S20 of the present invention is not limited to have to perform the first drive-in process. Please refer to FIG. 11, and refer to FIG. 3 and FIG. 6 again. FIG. 11 is a flow chart illustrating another example of forming the body region and the channel defining region in step S20 according to the first embodiment. As shown in FIG. 11, step S20 of this example includes the following steps:

Step S201: form a patterned mask on the substrate for defining positions of the body region and the channel defining region;

Step S204: perform a first ion implant process to form a first ion implant region having P type in the first well;

Step S205: perform a second ion implant process to form a second ion implant region having N type in the first ion implant region; and

Step S206: perform a drive-in process to form the body region in the first well and to form the channel defining region in the body region.

Please refer FIG. 3 again. Step S201 of another example first performs the first P type ion implant process 20 of step S204 to form the first ion implant region 22 in the first well 12 after forming the patterned mask 16 and the patterned photoresist layer 18. Then, the second N type ion implant process 26 of step S205 is performed to form the second ion implant region 28 in the first ion implant region 22. Next, as shown in FIG. 6, in step S206, the patterned photoresist layer 18 is first removed, and a drive-in process is then performed. The doped ions in the first ion implant region 22 and the second ion implant region 28 can simultaneously be laterally diffused during the drive-in process so as to form the body region 24 in the first well 12 and form the channel defining region 30 in the body region 24. Thereafter, the patterned mask 16 is removed. It should be noted that a mass of an ion implanted by the second N type ion implant process 26 is larger than a mass of an ion implanted by the first P type ion implant process 20 so as to have different lateral diffusion rates. For this reason, the difference between the area of the body region 24 and the area of the channel defining region 30 is generated so as to expose a part of the body region 24, which constitutes the channel 32 of LDMOS device. The channel length L of the present invention can be determined according to the dosages and implant positions of the first P type ion implant process 20 and the second N type ion implant process 26 as well as temperature and time of the second drive-in process. In addition, the step of removing the patterned photoresist layer 18 is not limited to be performed in step S206, and the step of removing the patterned photoresist layer 18 can be performed before the drive-in process. Furthermore, the step of removing patterned mask 16 also can be performed between step S205 and step S206. It should be noted that this embodiment uses a drive-in process to make the doped ions in the first ion implant region and the doped ions in the second ion implant region 28 simultaneously be laterally diffused, so this embodiment also can directly use single patterned photoresist layer to be the implant mask of the first ion implant region 22 and the second ion implant region 28.

Please refer to FIG. 1 and FIG. 7 through FIG. 9 again. The steps of forming the patterned photoresist layer as a mask before performing the ion implant process and removing the patterned photoresist layer after the ion implant process will not be redundantly in the following ion implant processes. As shown in FIG. 7, in step S30, a plurality of first isolation structures 34 is formed on the substrate 10 so as to isolate the LDMOS device and the other devices on the substrate 10. In this embodiment, a method of forming the first isolation structures 34 is a local oxidation of silicon (LOCOS) method, and each first isolation structure 34 is a field oxide (FOX). The present invention is not limited to this. The method of forming the first isolation structures 34 also can be a shallow trench isolation (STI) method, and each first isolation structure 34 is a STI structure. Then, in step S40, an N type ion implant process and a drive-in process is performed to form the grade region 36 in the other side of the first well 12 relative to the body region 24. The grade region can help to transfer current from the first well 12 or to the first well 12. Next, step S50 utilizes a third photomask to form a gate structure 38 on the substrate 10, and the gate structure 38 is disposed between a part of the grade region 36 and the channel defining region 30 so as to cover the whole channel 32. In addition, the gate structure 38 includes a gate 40 of the LDMOS device and a gate insulation layer 42, and the gate 40 and the gate insulation layer 42 can be formed by performing a deposition process and a lithographic and etching process. It should be noted that the present invention fixes the sizes of the channel defining region 30, the body region 24 and the first well 12, so that the overlap between the gate structure and the body region 24 forming the channel 24 will not change even if the second photomask for defining the position of the body region 24 and the third photomask for defining the position of the gate structure 38 have misalignment. Therefore, the channel length L of LDMOS device can be stable.

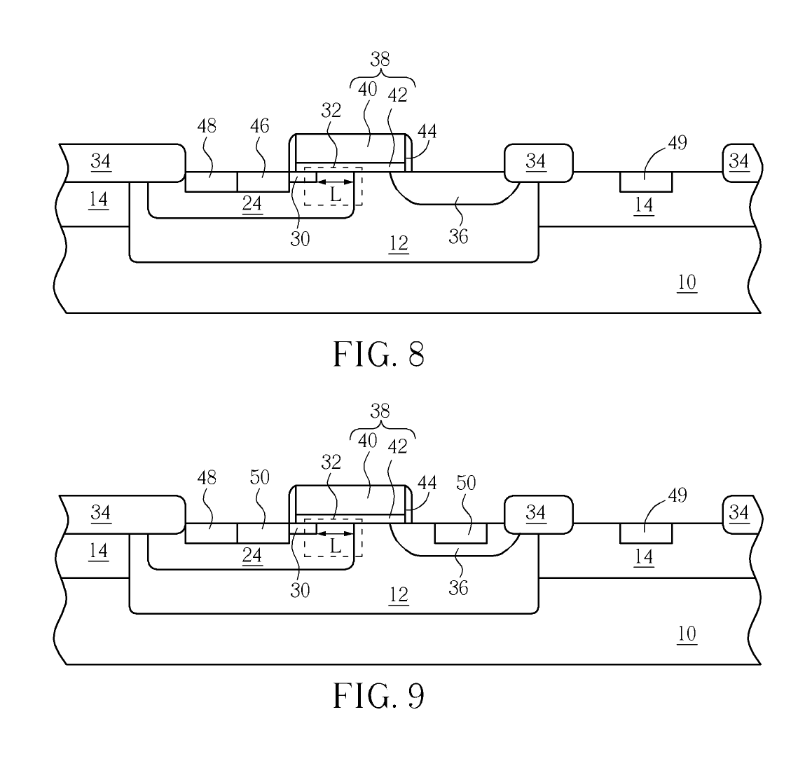

Then, as shown in FIG. 8, step S60 utilizes a deposition process and a dry etching process to form a spacer 44 surrounding the sidewall of the gate structure 38. The spacer 44 can be composed of insulating material, such as silicon nitride (Si₃N₄) or silicon oxide (SiO₂), and can be a single or multilayer structure. Next, step S70 performs an N type ion implant process to form a light doped region 46 having N type in the body region 24 of a side of gate structure 38. The light doped region 46 is in contact with the channel defining region 30 and is used for transfer the current from the channel defining region 30 or to the channel defining region 30. Thereafter, in step S80, a P type ion implant process and a drive-in process are performed to form a first heavy doped region 48 with P type in the body region 24 of the other side of the light doped region 46 opposite to the gate structure 38 and a third heavy doped region 49 in the second well 14. The first heavy doped region 48 is used to electrically connect the body doped region 24 regarded as a body of the LDMOS device to the outside. The third heavy doped region 49 is used to electrically connect the second well 14 to the outside.

Next, as shown in FIG. 9, step S90 performs an N type ion implant process and a drive-in process to form the second heavy doped regions 50. One of the second heavy doped regions 50 formed in the body region 34 between the first heavy doped region 48 and the gate structure 38 can be regarded as a source of the LDMOS device, and one of the second heavy doped regions 50 formed in the first well 12 of the other side of the gate structure 38 opposite to the body region 24 can be regarded as a drain of the LDMOS device. The LDMOS device is therefore finished. In addition, the second heavy doped region 50 regarded as the source is disposed between the gate structure 38 and the first heavy doped region 48, and the second heavy doped region 50 regarded as the drain is disposed in the grade region 36 and in contact with the grade region 36. Furthermore, the doped concentration of the second heavy doped region 50 regarded as the source is higher than the light doped region 46, and the depth of the second heavy doped region 50 regarded as the source is also deeper than the depth of the light doped region 46, so that step S70 of forming the light doped region 46 can be determined to be not performed on the condition that the second heavy doped region 50 regarded as the source is formed. In this condition, the second heavy doped region 50 regarded as the source is disposed between the first heavy doped region 48 and the channel defining region 30.

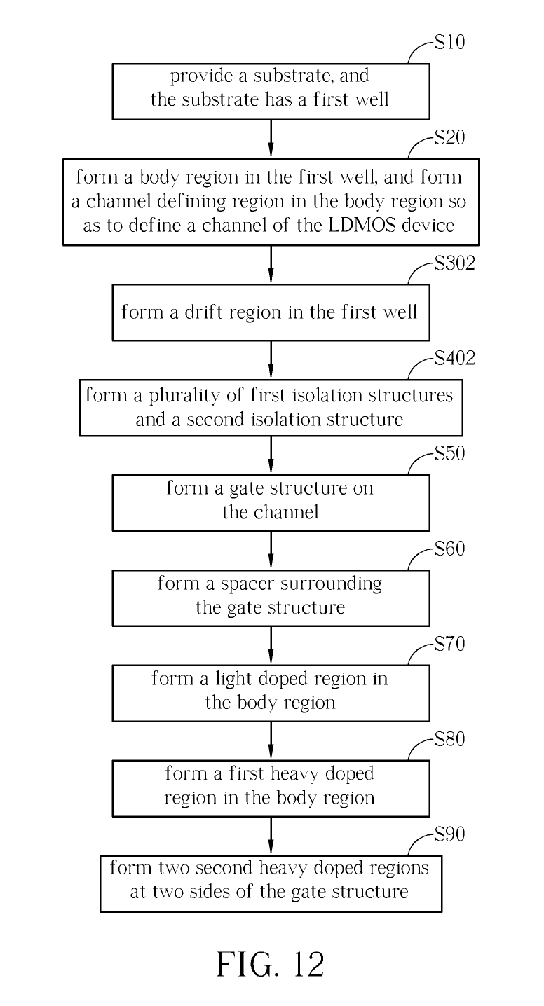

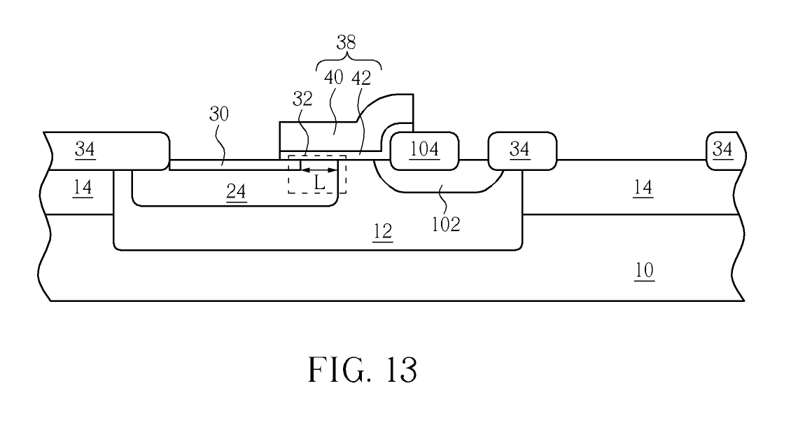

In addition, please refer to FIG. 12 and FIG. 13. FIG. 12 is a flow chart illustrating a method of manufacturing the LDMOS device according to a second embodiment of the present invention. FIG. 13 is a schematic diagram illustrating the method of manufacturing the LDMOS device according to the second embodiment of the present invention. As compared with the first embodiment, the method of the second embodiment is used to manufacture an LDMOS device, which gate structure near the drain end can tolerate high breakdown voltage. The method of the second embodiment before step S20 and after step S50 is the same as the first embodiment. In order to compare the difference between the embodiments, same steps of the second embodiment as the first embodiment will not be redundantly, and same devices use same symbols. As shown in FIG. 12, the method of manufacturing the LDMOS device of the second embodiment includes the following steps between step S20 and step S50:

Step S302: form a drift region in the first well; and

Step S402: form a plurality of first isolation structures at edges of the first well, and form a second isolation structure in the first well, wherein the drift region surrounds the second isolation structure.

As shown in FIG. 13, in step S302, the second embodiment performs an N type ion implant process and a drive-in process to form an N type drift region 102 in the first well 12. Then, step S402 is performed. As compared with step S30 of the first embodiment, step S402 of the second embodiment also forms a plurality of first isolation structure 34 at edges of the first well 12, and further includes forming a second isolation structure 104 in the N type drift region 102 of the first well 12. Thereafter, step S50 forms the gate structure 38 on the channel 32, and the gate structure 38 is formed on the second isolation structure 104, so that the second isolation structure can be used to avoid damage of the gate structure 38 resulted from the high pulse voltage into the drift region 102. Furthermore, the method of forming the first isolation structure 34 and the second isolation structure 104 of the second embodiment is the same as the first embodiment, and will not be mentioned redundantly.

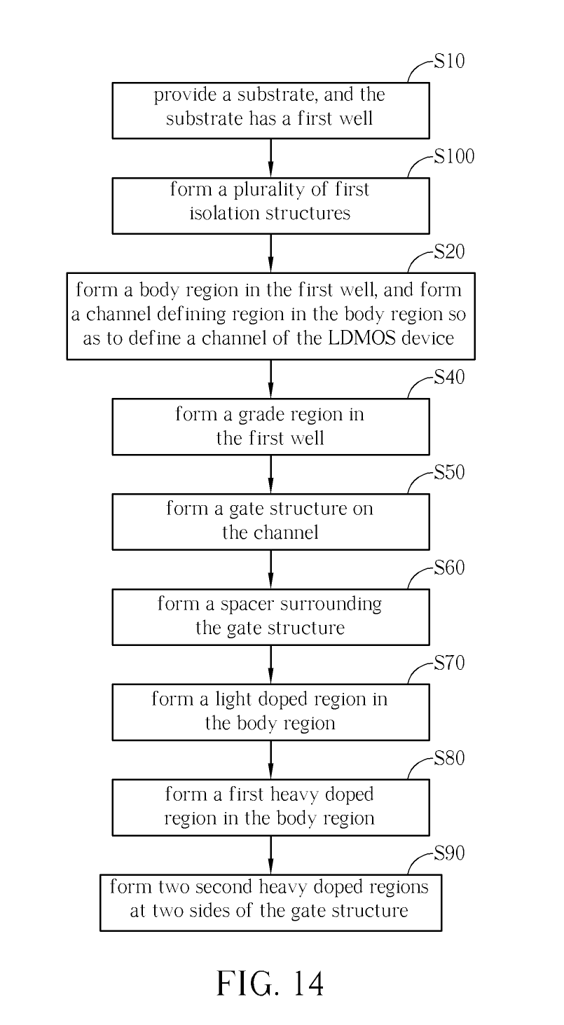

Please refer FIG. 14. FIG. 14 is a flow chart illustrating a method of manufacturing the LDMOS device according to a third embodiment of the present invention. As compared with the first embodiment, the method of manufacturing the LDMOS device of the third embodiment forms the first isolation structures before step S20 of forming the body region and the channel defining region. As shown in FIG. 14, the method of manufacturing the LDMOS device of the third embodiment further includes step S100 of forming a plurality of first isolation structures before step S20, and removes step S30. In addition, the method of forming the first isolation structure of the first embodiment is also the same as the first embodiment, and will not be mentioned redundantly.

As the above-mentioned description, the present invention forms the channel defining region, the body region and the first well before forming the gate structure, and respectively performs corresponding high temperature drive-in process to fix the sizes so as to stabilize the channel length. Then, the gate structure is formed, and the channel defining region and the body region are defined by a same patterned mask. For this reason, even the gate structure of the present invention formed on the substrate has misalignment in position, and the channel length disposed under the gate structure will not be affected in the condition of the gate structure covering the channel. Therefore, the channel length of the LDMOS device can be effectively stabilized, and the process window can be largely raised.

Those skilled in the art will readily observe that numerous modifications and alterations of the device and method may be made while retaining the teachings of the invention.

1. A method of manufacturing a lateral-diffusion metal-oxide-semiconductor (LDMOS) device, comprising:
providing a substrate, and the substrate having a well, wherein the substrate has a first conductive type, and the well has a second conductive type;
forming a body region having the first conductive type in the well, and forming a channel defining region having the second conductive type in the body region, wherein the body region between the doped region and the well and uncovered with the channel defining region forms a channel of the LDMOS;
forming a plurality of first isolation structures at edges of the well after forming the channel defining region; and
forming a gate structure on the channel.

2. The method of claim 1, further comprising forming a patterned mask on the substrate before forming the body region and the channel defining region, and the patterned mask being used to define positions of the body region and the channel defining region.

3. The method of claim 2, wherein the step of forming the body region and the channel defining region comprises:
performing a first ion implant process and a first drive-in process on the well exposed by the patterned mask so as to form the body region in the well; and
performing a second ion implant process and a second drive-in process on the body region exposed by the patterned mask so as to form the channel defining region in the body doped region.

4. The method of claim 1, wherein the step of forming the body region and the channel defining region comprises:
performing a first ion implant process to form a first ion implant region with the first conductive type in the well;
performing a second ion implant process to form a second ion implant region with the second conductive type; and
performing a drive-in process to form the body region in the well, and to form the channel defining region in the body region.

5. The method of claim 4, wherein a mass of an ion implanted by the second ion implant process is larger than a mass of an ion implanted by the first ion implant process.

6. The method of claim 1, further comprising a step of forming an annealing process after forming the body region and the channel defining region.

7. (canceled)

8. The method of claim 1, wherein a method of forming the first isolation structures is a local oxidation of silicon (LOCOS) method.

9. The method of claim 1, wherein a method of forming the first isolation structures is a shallow trench isolation (STI) method.

10. The method of claim 1, wherein the step of forming the first isolation structures further comprises forming a second isolation structure in the well.

11. The method of claim 10, further comprising forming a drift region having the second conductive type in the well, and the drift region surrounding the second isolation structure.

12. The method of claim 1, further comprising a step of forming a grade region having the second conductive type in the well before forming the gate structure.

13. The method of claim 1, further comprising a step of forming a spacer surrounding the gate structure after forming the gate structure.

14. The method of claim 13, further comprising a step of forming a light doped region having the second conductive type in the body region.

15. The method of claim 13, further comprising forming a first heavy doped region having the first conductive type in the body region.

16. The method of claim 13, further comprising a step of forming two second heavy doped regions having the second conductive type respectively in the body region between the first heavy doped region and the gate structure and in the well of the other side of the gate structure opposite to the body region.

17. (canceled)

18. The method of claim 1, wherein the gate structure comprises a gate insulation layer and a gate.
